(19) United States
(12) Patent Application Publication
(10) Pub. No.: US 2014/0339705 A1
(43) Pub. Date: Nov. 20, 2014

(54) IINTEGRATED CIRCUIT PACKAGE USING SILICON-ON-OXIDE INTERPOSER SUBSTRATE WITH THROUGH-SILICON VIAS

(71) Applicant: NVIDIA CORPORATION, Santa Clara, CA (US)

(72) Inventor: Abraham F. YEE, Cupertino, CA (US)

(73) Assignee: NVIDIA CORPORATION, Santa Clara, CA (US)

(21) Appl. No.: 13/897,010

(22) Filed: May 17, 2013

(51) Int. Cl. H01L 23/522; H01L 21/768

(52) U.S. Cl. CPC H01L 23/5226; H01L 21/76877
USPC 257/774; 438/125

(57) ABSTRACT

An integrated circuit package includes an integrated circuit package comprising an interposer and an integrated circuit die. The interposer is formed from a silicon-on-insulator semiconductor substrate and includes a plurality of through-silicon vias, and the integrated circuit die is electrically coupled to a first through-silicon via included in the plurality of through-silicon vias. Through-silicon vias in the integrated circuit package can be formed in the thin silicon surface layer of the silicon-on-insulator substrate, and therefore can be scaled down significantly in size. Such reduced-size through-silicon vias can be etched and filled much more cost-effectively and result in greatly reduced parasitic capacitance in the integrated circuit package.

### BACKGROUND OF THE INVENTION

1. Field of the Invention

Embodiments of the present invention relate generally to integrated circuit chip packaging and, more specifically, to an integrated circuit package using a silicon-on-oxide interposer substrate with through-silicon vias.

2. Description of the Related Art

In the packaging of integrated circuit (IC) chips, a key technology is the use of through-silicon vias (TSVs). TSVs are conductive paths formed entirely through an IC chip or silicon interposer, and help enable 3D chip design, which is a packaging design in which multiple IC chips are stacked or placed tightly side by side. In 3D chip design, signals can be transferred directly between chips in a chip package without using exceedingly long interconnect interconnect traces or wire bonds, thereby avoiding latency and crosstalk issues in the chip package.

Typically, when TSVs are formed through a silicon interposer, openings are etched into a silicon interposer substrate and filled with a conductive material, such as electroplated copper. For example, openings that are on the order of 5-10 microns in diameter and 50 to 100 microns deep may be used to form TSVs in a silicon interposer in this way. The interposer substrate is then thinned via grinding, polishing, and etching of the interposer substrate on the surface opposite the TSVs until the conductive material filling the TSVs is exposed. Thus, after thinning, the interposer substrate is 50 to 100 microns thick and the TSVs are formed completely through the remaining portion of the thinned silicon interposer substrate.

Etching openings in the silicon interposer substrate, depositing insulating dielectric and the conductive material in the openings, and thinning the silicon interposer substrate are all costly and time-consuming processes. In addition, the thinning process is difficult-to-control and generally involves trial-and-error, visual inspection, thickness measurements, and the like to ensure adequate process control.

Furthermore, for 3D chips, mismatch between the thermal expansion of the silicon and the conductive material forming TSVs in the interposer, such as copper, can create significant stresses in the 3D chip at operational temperatures. Due to the relatively large volume of conductive material that is present in TSVs, such stresses are sizable and can alter the threshold values of transistors anywhere nearby, thus changing the performance of the chip in somewhat unpredictable ways.

Consequently, chip packages generally include an exclusion zone free of transistors or other active devices surrounding each TSV. These exclusion zones reduce the effects of such stresses caused by the TSVs, but are are wasteful of valuable silicon surface area and increase path length between TSVs and ICs in the package electrically coupled to the TSVs.

Accordingly, there is a need in the art for an IC package that has smaller and more easily manufactured TSVs.

### SUMMARY OF THE INVENTION

One embodiment of the present invention sets forth a microelectronic package comprising an interposer and an integrated circuit die. The interposer is formed from a silicon-on-insulator semiconductor substrate and includes a plurality of through-silicon vias, and the integrated circuit die is electrically coupled to a first through-silicon via included in the plurality of through-silicon vias.

One advantage of the above-described embodiment is that through-silicon vias in a integrated circuit package can be formed in the top silicon layer of a silicon-on-insulator substrate, and therefore can be scaled down significantly in size. Such reduced-size, through-silicon vias can be etched and filled much more cost-effectively and result in greatly reduced parasitic capacitance in the integrated circuit package. Moreover, because the silicon interposer of the integrated circuit package can be formed from the thin silicon surface layer of the silicon-on-insulator substrate, the silicon interposer can be advantageously fabricated without imprecise and difficult-to-control thinning operations.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of an integrated circuit (IC) package, arranged according to one embodiment of the invention.

FIG. 2 is a schematic cross-sectional view of an IC package, arranged according to another embodiment of the invention.

FIG. 3 sets forth a flowchart of method steps for forming an IC package, according to an embodiment of the invention.

FIGS. 4A-4F sequentially illustrate the results of the different method steps of FIG. 3.

FIG. 5 illustrates a computing device in which one or more embodiments of the present invention can be implemented.

For clarity, identical reference numbers have been used, where applicable, to designate identical elements that are common between figures. It is contemplated that features of one embodiment may be incorporated in other embodiments without further recitation.

### DETAILED DESCRIPTION

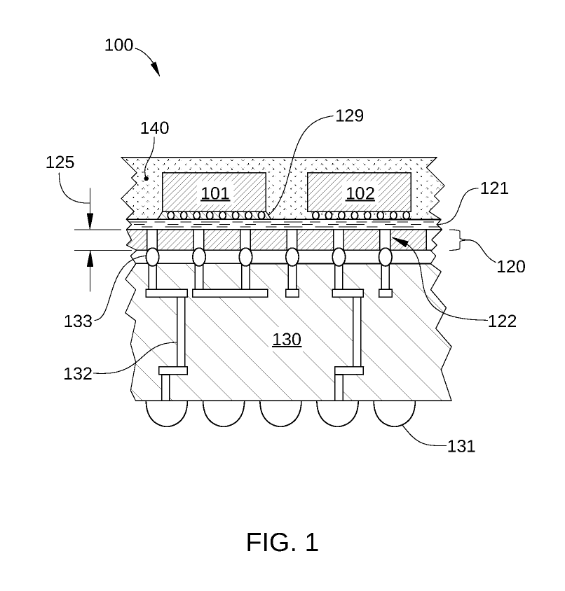

FIG. 1 is a schematic cross-sectional view of a IC package 100, arranged according to one embodiment of the invention. IC package 100 includes integrated circuit (IC) chips 101 and 102 coupled to a silicon silicon interposer 120, a packaging substrate 130 and an over-molding 140 formed over IC chips 101 and 102. IC package 100 is configured to electrically and mechanically connect IC chips 101, 102, and any other logic or memory ICs coupled to silicon interposer 120 to a printed circuit board or other mounting substrate (not shown) external to IC package 100. In addition, IC package 100 protects IC chips 101 and 102 from ambient moisture and other contamination and minimizes mechanical shock and stress thereon.

Each of IC chips 101 and 102 may be a semiconductor die singulated from a separately processed semiconductor substrate, such as a central processing unit (CPU), a graphics processing unit (GPU), an application processor or other logic device, a memory chip, a global positioning system (GPS) chip, a radio frequency (RF) transceiver chip, a Wi-Fi chip, a system-on-chip, or any semiconductor chip that is suitable for mounting on silicon interposer 120. Thus, IC chips 101 and 102 may include any IC chips that may benefit from being assembled together in a single microelectronic package. Moreover, in FIG. 1, IC package 100 is shown with two IC chips, but in other embodiments IC package 100 may be configured with more or fewer IC chips. Thus, in some embodiments, IC package 100 may be configured as a system-on-chip and may include a heterogeneous assortment of IC chips.

In some embodiments, IC chip 101 may be logic chip, such as a CPU or GPU, and IC chip 102 may be a memory chip associated with IC chip 101. IC chips 101 and 102 may be coupled to interposer substrate 120 using solder microbumps or any other technically feasible approach. In some embodiments, an underfill material 129 is used to protect the electrical connections between IC chips 101 and 102 and silicon interposer 120, and in other embodiments, underfill material 129 is not used. In FIG. 1, IC chip 101 is depicted with underfill material 129 and IC chip 102 is depicted without underfill material 129.

IC chips 101 and 102 are electrically coupled to each other with electrical interconnects formed in an interconnect layer 121 formed on silicon interposer 120. The electrical interconnects of interconnect layer 121 are configured to electrically couple IC chips 101 and 102 to each other and to through-silicon vias 122, which are formed in silicon interposer 120 and are described below. These electrical interconnects may include ground, power, and signal connections to each of IC chips 101 and 102, and can be formed on silicon interposer 120 using various wafer-level deposition, patterning, and etching processes, i.e., processes that are performed on a complete semiconductor wafer or other substrate. In this way, interconnect layer 121 can be formed simultaneously on a complete semiconductor substrate for a plurality of IC packages, and the semiconductor substrate is subsequently singulated into individual interposer elements, such as silicon interposer 120, with interconnect layer 121 already formed thereon. Thus, IC package 100 may be formed on one such singulated interposer element.

In some embodiments, the electrical interconnects of interconnect layer 121 are formed using one or more deposition, patterning, and etching techniques used for forming the interconnects between the transistors of an integrated circuit. Thus, in such embodiments, interconnect layer 121 may include one or more levels of electrical interconnects, such as electroplated copper (Cu) or sputtered aluminum (Al), that are formed in alternating layers of an insulative material, such as silicon dioxide. Interconnect layer 121 may further include a final passivation layer for protecting the top layer of electrical interconnects, and may be bumped with a conductive material, such as solder, for making electrical connections directly to IC chips 101 and 102. Interconnect layer 121 and through-silicon vias 122 effectively provide very short electrical connections between IC chips 101 and 102 and to an external packaging substrate.

Silicon silicon interposer 120 includes an intermediate silicon layer or structure that provides electrical connections between IC chips 101 and 102, any other semiconductor chips mounted on silicon interposer 120, and any technically feasible mounting substrate. For example, the mounting substrate may be a packaging substrate included in IC package 100, such as packaging substrate 130, or a printed circuit board external to IC package 100. Generally, silicon interposer 120 may be electrically coupled to mounting substrate 130 with through-silicon vias 122 using any technically feasible electrical connection known in the art, including a ball-grid array (BGA), a pin-grid array (PGA), and the like.

According to embodiments of the invention, silicon interposer 120 is formed from a top silicon layer of a silicon-on-insulator (SOI) semiconductor substrate, and therefore can be much thinner than a silicon interposer formed from a conventional silicon substrate. This is because an SOI semiconductor substrate can be acquired off-the-shelf with a top silicon layer having a specific and precisely known thickness. Currently, SOI substrates are available with top silicon layers that are as thin as a few 10s of nanometers or as thick as a few microns, and the thickness of the top silicon layer can be accurately selected to within a few nanometers. In contrast, the formation of a silicon interposer from a conventional silicon substrate generally involves thinning the conventional silicon substrate from a starting thickness of 750 to 800 microns down to a final thickness of about 50 to 100 microns, the thinning process ultimately exposing the TSVs formed therein so that a conductive pathway is provided entirely through the silicon interposer. Thinning of a silicon substrate to less than 50 microns is problematic, since the substrate can be easily cracked during thinning and subsequent handling. In addition, to prevent warpage of thinned silicon substrates, TSVs formed therein are generally configured with a diameter of 5, 10, or more microns in order to stiffen the thinned silicon substrate and reduce warpage.

The difficulties associated with precisely thinning a silicon substrate down to a thickness of 100 microns or less are manifold. First, the thinning process is time-consuming and costly, typically involving multiple steps, including grinding, chemical-mechanical polishing, and silicon etching. Second, the thinning process is difficult to control, since the actual thickness of the silicon substrate is difficult to determine accurately while material is being removed therefrom. Third, handling silicon substrates thinned to 100 microns or less without cracking the substrate is challenging. Consequently, the silicon substrate being thinned usually undergoes the additional process steps of bonding to a silicon or glass carrier prior to thinning and debonding from the carrier after thinning, the carrier being used as a mechanism for handling the substrate. Furthermore, even when the silicon interposer is successfully thinned and de-bonded from the carrier without damage, the final thickness of the silicon interposer is generally much thicker than the top silicon layer of an SOI substrate that can be readily acquired off-the-shelf. For example, SOI substrates can be purchased with a top silicon layer having a thickness of about 10 microns down to 10s of nanometers, thicknesses that are one or more orders of magnitude thinner than a silicon substrate thinned down to 50 to 100 microns.

Through-silicon vias (TSVs) 122 are “micro vias” formed through silicon interposer 120, and may be configured to electrically couple IC chips 101 and 102 to a packaging substrate included in IC package 100 or to a printed circuit board external to IC package 100. Because silicon interposer 120 is not formed from a thinned silicon substrate subject to significant warpage, TSVs 122 so not need to provide structural rigidity during a thinning process, and can be configured with smaller dimensions. Thus, rather than being 50 to 100 microns deep and having a diameter of 5-10 microns, which is typical for TSVs formed in a silicon interposer formed by a thinning process, TSVs 122 may be from 10 nm to 1 micron in diameter. Consequently, TSVs 122 can be formed in silicon interposer 120 using standard integrated circuit fabrication processes, including the patterning, etching, and filling processes used to form submicron interconnects in an integrated circuit. For example, in some embodiments, a typical process for forming a contact in an integrated circuit may be used to form TSVs 122, which is a well-known, easily controlled, and reliable process.

Because thickness 125 can be 10 microns, 1 micron, or less, openings for TSVs 122 can be formed quickly in silicon interposer 120. Furthermore, because the aspect ratio of these openings can be selected to be relatively low, for example less than about 10:1, these openings can be filled quickly and reliably, for example, with aluminum, copper, tungsten (W), and the like. Moreover, the volume of each of TSVs 122 is advantageously much less than the typical volume of TSVs formed in a silicon interposer formed by a thinning process. For example, when silicon interposer 120 has a thickness 125 of 100 nm, a TSV 122 with a diameter of 100 nm has a volume that is approximately ten million time less than that of a TSV having a diameter of 10 microns and a depth of 100 microns. Less conductive material in TSVs 122 results in less parasitic capacitance during operation of IC chips 101 and 102. In addition, less volume of conductive material in TSVs 122 results in less stresses in IC package 100 caused by thermal mismatch between the conductive material and silicon interposer 120. Thus, in some embodiments, IC package 100 can be configured without exclusion zones for TSVs 122. In other words, TSVs 122 can be positioned very close to transistors and other semiconductor devices in IC package 100 without significantly affecting the performance of these semiconductor devices.

Packaging substrate 130 can be a rigid and thermally insulating substrate on which interposer 120 is mounted and provides IC package 100 with structural rigidity. Electrical connections 133 provide electrical connections between interposer 120 and packaging substrate 130, and may be any technically feasible electrical connection known in the art, for example C4 bumps formed on either substrate 120 or packaging substrate 130. In some embodiments, packaging substrate 130 is a laminate substrate and is composed of a stack of insulative layers or laminates that are built up on the top and bottom surfaces of a core layer. Packaging substrate 130 also provides an electrical interface for routing input and output signals and power between IC chips 101 and 102 and electrical connections 131. Electrical connections 131 provide electrical connections between IC package 100 and a printed circuit board or other mounting substrate external to IC package 100. Electrical connections 131 may be any technically feasible chip package electrical connection known in the art, including a ball-grid array (BGA), a pin-grid array (PGA), and the like. Packaging substrate also includes vias and interconnects 132 that route input and output signals and power between electrical connections 131 and electrical connections 133.

Overmolding 140 is formed on silicon interposer 120 and encapsulates IC chips 101 and 102. Overmolding 140 may be an injection-molded component formed from a mold compound using an injection molding process. The material of overmolding 140 is selected to protect IC chips 101 and 102 from mechanical damage, exposure to moisture, and other ambient contamination. Overmolding 140 can also act as a stiffener to reduce warpage. In some embodiments, overmolding 140 can be configured so that IC chips 101 and 102 are not covered, in order to add a heatsink or heatspreader directly to IC chips 101 and/or 102 for effective heat removal. Alternatively, overmolding 140 can be planarized using a chemical-mechanical polishing process to remove molding material covering IC chips 101 and 102 and facilitate the addition of a heatsink or heatspreader directly to IC chips 101 and/or 102 for effective heat removal.

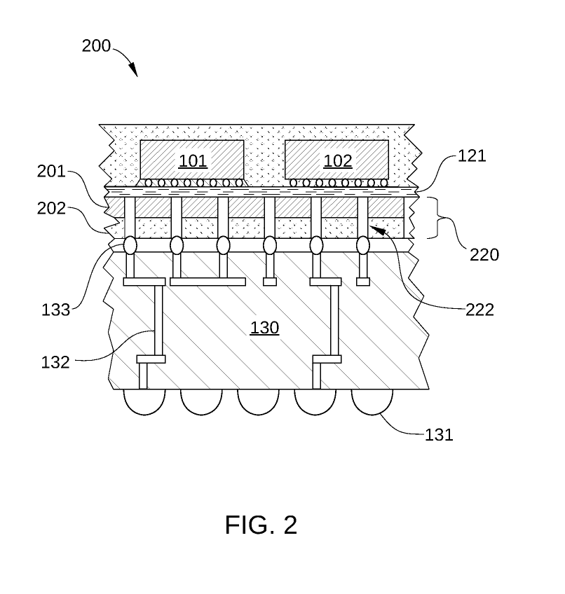

FIG. 2 is a schematic cross-sectional view of an IC package 200, arranged according to another embodiment of the invention. IC package 200 may be substantially similar in configuration and operation to IC package 100 in FIG. 1, except that IC package 200 includes a silicon interposer 220 that is formed from a silicon layer 201 of an SOI semiconductor substrate and a dielectric layer 202 of the SOI semiconductor substrate. An SOI semiconductor substrate generally includes a top silicon layer and a buried oxide layer formed on a device surface of the bulk silicon portion of the SOI semiconductor substrate. In the embodiment illustrated in FIG. 2, top silicon layer 201 is formed from the top silicon layer of the SOI semiconductor substrate and dielectric layer 202 is formed from the buried oxide layer of the SOI semiconductor substrate. As shown, dielectric layer 202 forms a lower passivation layer that is penetrated by TSVs 222 and is disposed between silicon interposer 220 and packaging substrate 130.

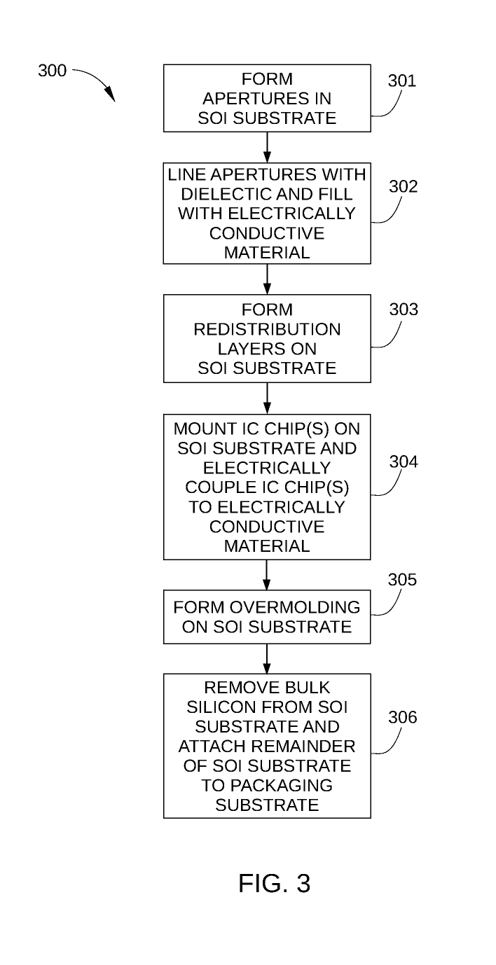

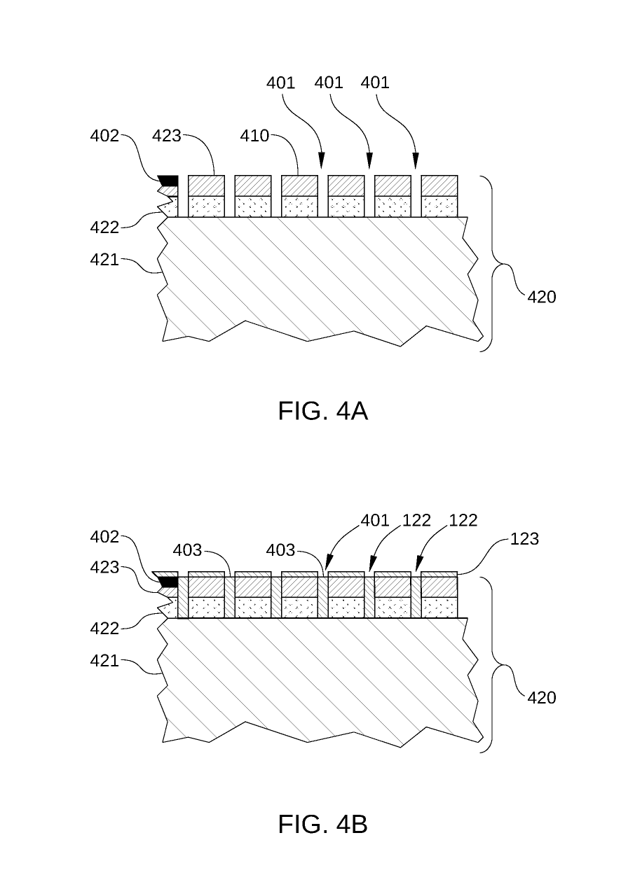

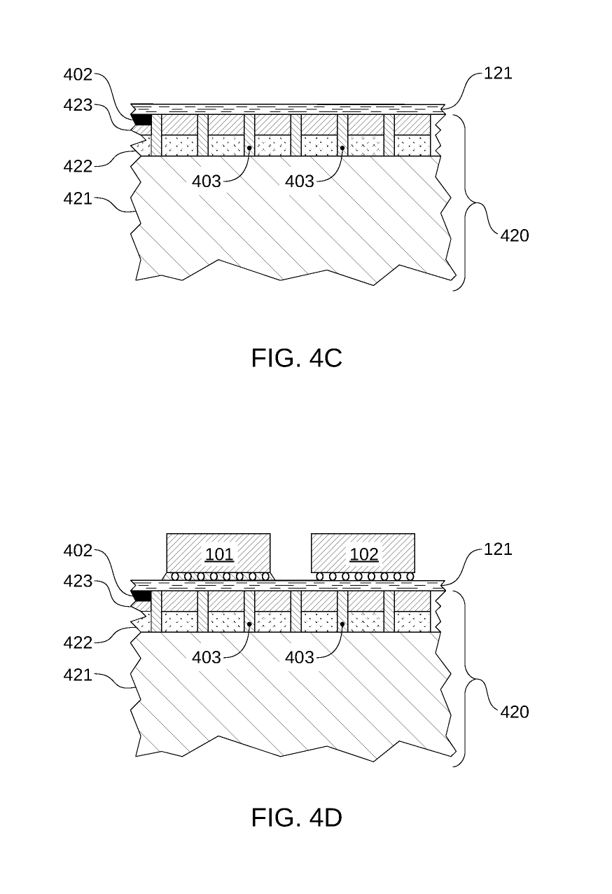

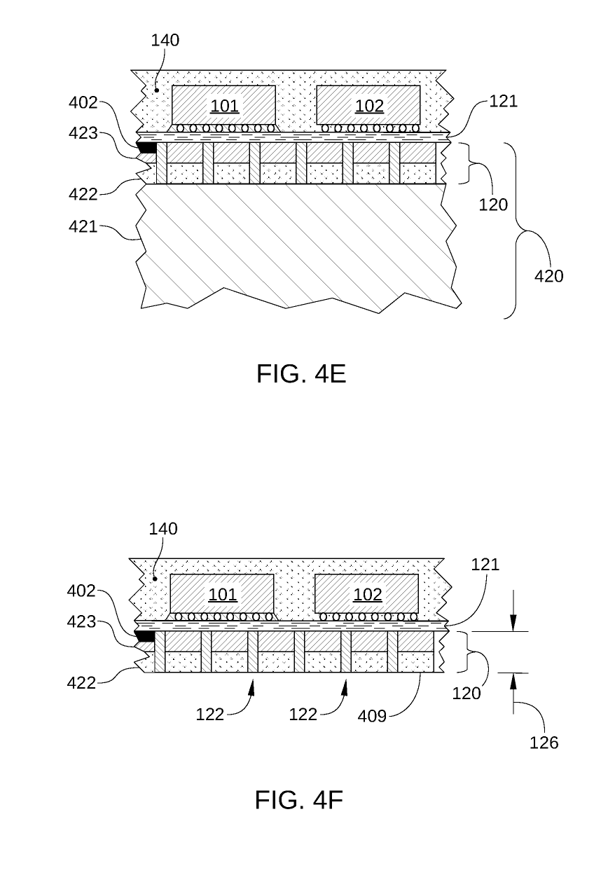

FIG. 3 sets forth a flowchart of method steps for forming an integrated circuit interposer package, according to an embodiment of the invention. Although the method steps are described with respect to IC package 100 of FIG. 1 and IC package 200 of FIG. 2, persons skilled in the art will understand that performing the method steps, in any order, to form other configurations of IC package is within the scope of the invention. For clarity, FIGS. 4A-4F sequentially illustrate the results of steps 301-305 of FIG. 3.

In some embodiments, prior to performing method 300, one or more transistors or other semiconductor devices 402 may be formed on device surface 410 of an SOI substrate 420. Semiconductor devices 402 may be transistors, memory capacitors, passive components, and the like, as well as interconnect layers associated therewith, and are shown in FIGS. 4A-4F. Semiconductor devices 402 embodiments may include functional circuits such as microprocessors, graphic processors, memory, power management systems and the like.

The method 300 begins at step 301, where apertures 401 are formed in an SOI substrate 420, as shown in FIG. 4A. SOI substrate 420 includes a bulk silicon portion 421, a buried oxide layer 422, and a top silicon layer 423. Bulk silicon portion 421 may be a monocrystalline silicon layer making up the bulk of SOI substrate 420, buried oxide layer 422 is a dielectric material, such as silicon dioxide (SiO₂) or sapphire (α-Al₂-O₃), and top silicon layer 423 is a very thin monocrystalline silicon layer. In some embodiments, apertures 401 are formed through top silicon layer 423 to expose buried oxide layer 422, and in other embodiments, apertures 401 are formed through top silicon layer 423 and through buried oxide layer 422, to expose bulk silicon portion 421. To form an IC package similar to IC package 100 in FIG. 1, apertures 401 are formed through top silicon layer 423, and to form an IC package similar to IC package 200 in FIG. 2, apertures 401 are formed through top silicon layer 423 and through buried oxide layer 422 (as shown in FIG. 4A). Apertures 401 may be formed in step 301 using semiconductor patterning and etching techniques known in the art, such as reactive ion etching (RIE).

In step 302, apertures 401 are first lined with a layer of insulating dielectric 123, for example using a chemical vapor deposition process, and then filled with an electrically conductive material 403, such as electroplated copper, sputtered aluminum, tungsten deposited via chemical vapor deposition, and the like, as shown in FIG. 4B.

In some embodiments, a seed layer, a barrier layer, or other conformal layer of conductive material may be deposited in apertures 401 prior to the process of filling apertures 401 with electrically conductive material 403. When apertures 401 are filled with electrically conductive material 403, TSVs 122 are formed in SOI substrate 420, although in step 302 TSVs 122 do not yet form an electrically conductive path through SOI substrate 420. After bulk silicon portion 421 is removed, as described below, TSVs 122 provide such electrically conductive paths.

In step 303, insulating dielectric 123 is prepared for the mounting of IC chips 101 and 102 on SOI substrate 420, as shown in FIG. 4C. Specifically, one or more layers of electrical interconnects may be formed on SOI substrate 420, such as interconnect layer 121. Interconnect layer 121 may be formed using various wafer-level deposition, patterning, and etching processes known in the art, and may be configured to electrically couple IC chips 101 and 102 to each other and to electrically conductive material 403 in one or more of the apertures 401. In some embodiments, different layers of electrical interconnects in interconnect layer 121 are formed within insulative, non-organic dielectric films that are deposited on a surface of SOI substrate 420. For example, in some embodiments, insulating dielectric 123 is patterned, etched, and filled using conventional dual damascene metal deposition processes to form interconnect layer 121. A chemical-mechanical polishing process may then be used after such processes are used to form a layer of interconnect layer 121. The above processes may be repeated for additional interconnect layer in interconnect layer 121, the final interconnect layer including top layer pads for electrical connection to IC chips 101 and 102.

In step 304, IC chips 101 and 102 are mounted on SOI substrate 420 and electrically coupled to electrically conductive material 403 in one or more of the apertures 401 formed in top silicon layer 423, as shown in FIG. 4D. For example, IC ships 101 and 102 may be mechanically and electrically coupled to SOI substrate 420 with solder microbumps in a reflow process or other thermal process, such as thermal compression non-conductive paste (TCNCP).

In step 305, overmolding 140 is formed on SOI substrate 420 to encapsulate IC chips 101 and 102, as shown in FIG. 4E. Overmolding 140 may be an injection-molded component formed by injecting a suitable molten material, such as a molding compound, into a mold cavity or chase using techniques known in the art. The mold cavity may be formed with a removable mold assembly (not shown in FIG. 1 for clarity) coupled to silicon interposer 120. After cooling and hardening of the molding compound and removal of the mold assembly, the injected molding compound forms overmolding 140 as shown in FIG. 1. In some embodiments, overmolding 140 for a plurality of IC packages can be formed simultaneously with a single mold assembly prior to singulation of IC package 100. The material of overmolding 140 is selected to protect IC chips 101 and 102 from mechanical damage, exposure to moisture, and other ambient contamination. Overmolding 140 can be planarized using a chemical-mechanical polishing process to remove molding material covering IC chips 101 and 102 and facilitate the addition of a heatsink or heatspreader directly to IC chips 101 and/or 102 for effective heat removal.

In step 306, bulk silicon portion 421 is removed from SOI substrate 420, thereby forming silicon interposer 120 and exposing TSVs 122 on bottom surface 409 of silicon interposer 120, as shown in FIG. 4F. Various material removal methods may be used to remove bulk silicon portion 421 in step 306. For example, a back-grinding process may be used to remove the majority of bulk silicon portion 421, followed by a chemical-mechanical polishing (CMP) and an etching process to remove the remaining silicon material. In some embodiments, the presence of buried oxide layer 422 can be used as an etch stop during the material removal processes in step 306. Thus, a bulk removal process, such as a CMP process, can be used to remove material from the bulk silicon side of SOI substrate until the removal of the dielectric material making up buried oxide layer 422 is detected. In this way, the material removal process of step 306 can be very precisely controlled and a targeted thickness 126 for silicon interposer 120 can be achieved when silicon interposer 120 includes buried oxide layer 422 and top silicon layer 421.

In some embodiments, buried oxide layer 422 is also removed from SOI substrate 420, so that silicon interposer 120 includes top silicon layer 423 but not buried oxide layer 422. Top silicon layer 423 includes a different material (e.g., silicon) than the material of buried oxide layer 422 (e.g., silicon dioxide). Consequently, in such embodiments, the material removal process in which buried oxide layer 422 is removed can be very precisely controlled by using top silicon layer 423 as an etch stop. Thus, even though silicon interposer 120 may be one or more orders of magnitude thinner than a silicon interposer formed from a conventional silicon substrate, thickness 125 of silicon interposer 120 can still be precisely controlled.

Because etch stops can be used to control the thinning process of step 306, when method 300 is used to form silicon interposer 120, the typical inspections that a silicon interposer undergoes after each step of a thinning process may be avoided, thereby simplifying the fabrication process. Inspections that may no longer be necessary when method 300 is used to form a silicon interposer include thickness measurements of the silicon interposer, crack detection, inspection for mechanical damage to the silicon substrate caused by the debonding or thinning processes, inspection for residual bonding adhesive or other foreign matter, etc.

In some embodiments, prior to the material removal process in step 306, a glass or silicon carrier may be bonded to overmolding 140 to facilitate handling of SOI substrate 420 during the material removal process. In other embodiments, overmolding 140 can serve as an adequate mechanism by which SOI substrate 420 is handled during material removal.

After silicon interposer 120 is formed by the removal of bulk silicon portion 42 from SOI substrate 420 and TSVs 122 are exposed, a low-temperature dielectric can be deposited on bottom surface 409, e.g., at a temperature less than about 200° C. The dielectric layer can then be patterned, etched, filled, and planarized, using standard techniques, to form a bottom-side pad layer for the attachment of C4 bumps and subsequent mounting of silicon interposer 120 onto a packaging substrate, such as packaging substrate 130 in FIG. 1. Standard flip-chip ball-grid array (FCBGA) assembly processes may be used for attachment to the packaging substrate.

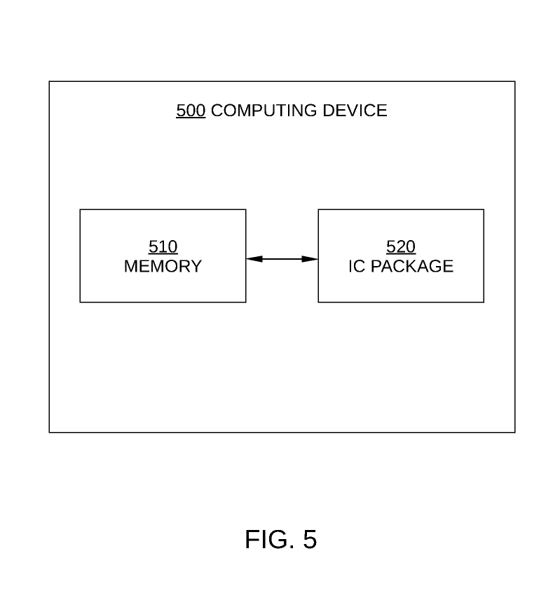

FIG. 5 illustrates a computing device in which one or more embodiments of the present invention can be implemented. Specifically, FIG. 5 is a block diagram of a computing device 500 with an IC package 520 configured according to an embodiment of the present invention. As shown, computer system 500 includes a memory 510 and an IC package 520 that is coupled to memory 510. Computer system 500 may be a desktop computer, a laptop computer, a smartphone, a digital tablet, a personal digital assistant, or other technically feasible computing device. Memory 510 may include volatile, non-volatile, and/or removable memory elements, such as random access memory (RAM), read-only memory (ROM), a magnetic or optical hard disk drive, a flash memory drive, and the like. IC package 520 may be substantially similar in organization and operation to IC packages 100 or 200, described above in conjunction with FIGS. 1 and 2, and may include a CPU, a GPU, an application processor or other logic device, a system-on-chip, or any other IC chip-containing device.

In sum, an embodiment of the invention sets forth an IC package that includes a silicon interposer formed from a silicon-on-insulator semiconductor substrate and method of manufacturing the same. Because the silicon interposer can be formed from the thin top silicon layer of the silicon-on-insulator substrate, through-silicon vias formed in the silicon interposer can be scaled down significantly in size. Such reduced-size through-silicon vias can be etched and filled much more cost-effectively and result in greatly reduced parasitic capacitance in the integrated circuit package. Moreover, because the silicon interposer of the integrated circuit package can be formed from the thin top silicon layer of the silicon-on-insulator substrate, the silicon interposer can be advantageously fabricated without imprecise and difficult-to-control thinning operations.

While the foregoing is directed to embodiments of the present invention, other and further embodiments of the invention may be devised without departing from the basic scope thereof, and the scope thereof is determined by the claims that follow.

I claim:

1. A microelectronic package, comprising:
an interposer that is formed from a silicon-on-insulator semiconductor substrate and includes a plurality of through-silicon vias; and
an integrated circuit die electrically coupled to a first through-silicon via included in the plurality of through-silicon vias.

2. The microelectronic package of claim 1, wherein the integrated circuit die is electrically coupled to the first through-silicon via with an electrically conductive interconnect.

3. The microelectronic package of claim 2, wherein the electrically conductive interconnect is formed in a non-organic dielectric material.

4. The microelectronic package of claim 1, further comprising an additional integrated circuit die electrically coupled to a second through-silicon via included in the plurality of through-silicon vias.

5. The microelectronic package of claim 1, wherein the interposer comprises a silicon layer of the silicon-on-insulator semiconductor substrate, the silicon layer having a thickness of less than about ten microns.

6. The microelectronic package of claim 1, wherein the interposer comprises an oxide layer of the silicon-on-insulator semiconductor substrate and a silicon layer of the silicon-on-insulator semiconductor substrate that has a thickness of less than about ten microns.

7. The microelectronic package of claim 6, wherein the plurality of through-silicon vias is formed through the oxide layer and the silicon layer.

8. The microelectronic package of claim 1, further comprising a semiconductor device formed on the silicon-on-insulator semiconductor substrate.

9. The microelectronic package of claim 8, wherein the semiconductor device is electrically coupled to the integrated circuit die.

10. A method for forming a microelectronic package, the method comprising:
forming an aperture in a silicon surface of a silicon-on-insulator substrate;
filling the aperture with an electrically conductive material; and
electrically coupling an integrated circuit die to the electrically conductive material.

11. The method of claim 10, further comprising forming the aperture in a dielectric layer of the silicon-on-insulator substrate.

12. The method of claim 10, further comprising forming an electrically conductive interconnect on the silicon-on-insulator substrate.

13. The method of claim 12, wherein the electrically conductive interconnect is configured to electrically couple the integrated circuit die to the electrically conductive material.

14. The method of claim 12, further comprising depositing a non-organic dielectric film on the silicon surface, wherein the electrically conductive interconnect is formed within the non-organic dielectric film.

15. The method of claim 10, wherein forming the aperture in the silicon surface comprises forming the aperture through a silicon layer of the silicon-on-insulator substrate to expose a dielectric layer of the silicon-on-insulator.

16. The method of claim 10, wherein forming the aperture in the silicon surface comprises forming the aperture through a silicon layer of the silicon-on-insulator substrate and a dielectric layer of the silicon-on-insulator substrate.

17. The method of claim 10, further comprising, prior to forming the aperture, forming a semiconductor device on the silicon surface.

18. The method of claim 17, further comprising electrically coupling the semiconductor device to the integrated circuit die.

19. The method of claim 10, further comprising removing a silicon material from a surface of the silicon-on-insulator substrate that is not the silicon surface to expose the electrically conductive material.

20. A computing device, comprising:
a memory; and
a microelectronic package coupled to the memory, wherein the microelectronic package comprises:
an interposer that is formed from a silicon-on-insulator semiconductor substrate and includes a plurality of through-silicon vias, and
an integrated circuit die electrically coupled to a first through-silicon via included in the plurality of through-silicon vias.
